(19) United States
(12) Patent Application Publication
(10) Pub. No.: US 2025/0204250 A1
(43) Pub. Date: Jun. 19, 2025

(54) NOVEL ORGANIC MONOMOLECULAR COMPOUND WITH MODIFIED ELECTRON TRANSPORT CHARACTERISTICS, AND DEVICE INCLUDING SAME

(71) Applicant: PUKYONG NATIONAL UNIVERSITY INDUSTRY-UNIVERSITY COOPERATION FOUNDATION, Busan (KR)

(72) Inventors: Jae Won CHANG, Busan (KR); Bo Ram LEE, Busan (KR); Seok Woo LEE, Daegu (KR)

(73) Assignee: PUKYONG NATIONAL UNIVERSITY INDUSTRY-UNIVERSITY COOPERATION FOUNDATION, Busan (KR)

(21) Appl. No.: 19/062,324

(22) Filed: Feb. 25, 2025

Related U.S. Application Data
(63) Continuation of application No. PCT/KR2023/012201, filed on Aug. 17, 2023.

(30) Foreign Application Priority Data
Aug. 26, 2022 (KR) 10-2022-0107859

(51) Int. Cl. H10K 85/60; C07F 9/6509; C09K 11/06; H10K 50/15; H10K 50/16; H10K 71/12; H10K 85/10

(52) U.S. Cl. CPC H10K 85/6572; C07F 9/650994; C09K 11/06; H10K 85/1135; H10K 85/114; H10K 85/151; C09K 2211/1425; H10K 50/15; H10K 50/16; H10K 71/12

(57) ABSTRACT

The present invention relates to an organic monomolecular compound having an alkoxy functional group in a chemical structure comprising a quinoxaline-based compound and a triphenylphosphine oxide-based compound. Specifically, the invention provides an organic monomolecular compound represented by Formula 1, as well as a device comprising the compound and a method for manufacturing the device.

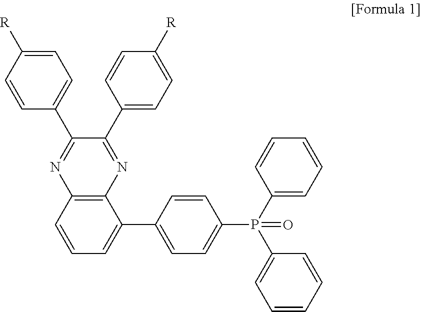

(In Formula 1, R is a substituted or unsubstituted alkoxy group having 1 to 20 carbon atoms.)

### CROSS-REFERENCE TO RELATED APPLICATIONS

This application is a continuation of International Application No. PCT/KR2023/012201 filed on Aug. 17, 2023, which claims priority to Korean Patent Application No. 10-2022-0107859 filed on Aug. 26, 2022, the entire contents of which are herein incorporated by reference.

### TECHNICAL FIELD

The present invention relates to a compound that can be used as an electron transport material for various optoelectronic devices, such as light-emitting devices and photodetectors, and a device comprising the same.

### BACKGROUND ART

In organic or perovskite optoelectronic devices, such as organic solar cells (OSC), organic light-emitting devices (OLED), perovskite solar cells (PSC), and perovskite light-emitting devices (PeLED), an electron transport layer material plays a role in facilitating the smooth transfer of electrons between the cathode and the active layer. Typically, alkali-based materials, such as lithium fluoride (LiF), which is based on inorganic compound materials, are widely used as electron transport layer materials.

However, electron transport layers utilizing lithium fluoride (LiF) and similar materials exhibit high reactivity to moisture and oxygen, thereby affecting the stability of the device. Consequently, an additional encapsulation process is required. Furthermore, since these materials are fabricated through a vacuum thermal evaporation process, they involve higher time and cost compared to solution-based processes.

### SUMMARY

### Technical Problem

An object of the present invention is to provide a novel organic monomolecular compound that enables film formation through a solution process and allows easy modification of electron transport properties, and a device including the same.

### Technical Solution

The present invention provides an organic monomolecular compound having an alkoxy functional group in a chemical structure comprising a quinoxaline-based compound and a triphenylphosphine oxide-based compound, wherein the organic monomolecular compound is represented by Formula 1 below.

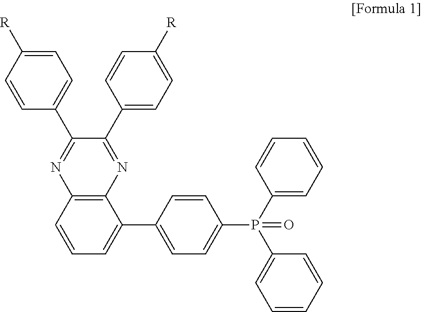

(In Formula 1, R is a substituted or unsubstituted alkoxy group having 1 to 20 carbon atoms)

Furthermore, the present invention provides an organic monomolecular compound, wherein R in Formula 1 is a methoxy group.

In another aspect, the present invention provides a device comprising a layer including the organic monomolecular compound.

Additionally, the present invention provides a device comprising a layer including the organic monomolecular compound, wherein the device comprises a substrate, a first electrode disposed on the substrate, a first charge transport layer disposed on the first electrode, an active layer disposed on the first charge transport layer, a second charge transport layer disposed on the active layer, and a second electrode disposed on the electron transport layer, wherein the first charge transport layer or the second charge transport layer comprises the organic monomolecular compound.

Moreover, the present invention provides a device, wherein the substrate is made of glass or plastic.

The present invention also provides a device, wherein the first electrode comprises at least one selected from the group consisting of indium tin oxide (ITO), fluorine tin oxide (FTO), aluminum zinc oxide (AZO), gallium zinc oxide (GZO), indium zinc oxide (IZO), zinc tin oxide (ZTO), indium zinc tin oxide (IZTO), and indium gallium zinc oxide (IGZO).

Furthermore, the present invention provides a device comprising a substrate, a first electrode disposed on the substrate, a hole transport layer disposed on the first electrode, an active layer disposed on the hole transport layer, an electron transport layer disposed on the active layer, wherein the electron transport layer includes the organic monomolecular compound, and a second electrode disposed on the electron transport layer.

Additionally, the present invention provides a device, wherein the hole transport layer comprises at least one selected from the group consisting of poly(ethylenedioxythiophene):polystyrene sulfonate (PEDOT:PSS), poly[(9,9-dioctyl-fluorenyl-2,7-diyl)-co-(4,4′-(N-(p-butylphenyl))diphenylamine)](TFB), poly(9-vinylcarbazole) (PVK), N,N,N′,N′-tetrakis(4-methoxyphenyl)-benzidine (TPD), poly-TPD, 4,4′,4″-tris(N-carbazolyl)-triphenylamine (TCTA), N,N′-bis(naphthalen-1-yl)-N,N′-bis(phenyl)-9,9-spiro-bifluorene (spiro-NPB), dipyrazino[2,3-f:2′,3′-h]quinoxaline-2,3,6,7,10,11-hexacarbonitrile (HATCN), 1,1-bis[(di-4-tolylamino)phenylcyclohexane (TAPC), VNPB (N4,N4′-Di(naphthalen-1-yl)-N4,N4′-bis(4-vinylphenyl)biphenyl-4,4′-diamine), and p-type metal oxide.

The present invention also provides a device further comprising a hole injection layer disposed between the first electrode and the hole transport layer, and an electron injection layer disposed between the second electrode and the electron transport layer.

Additionally, the present invention provides an organic light-emitting device having a sequentially laminated structure, comprising a glass substrate, an ITO electrode formed on the glass substrate, a hole transport layer formed on the ITO electrode and including PEDOT:PSS, an emission layer formed on the hole transport layer and including poly(phenylvinylene), an electron transport layer formed on the emission layer and including (4-(2,3-bis(4-methoxyphenyl)quinoxali-5-yl)phenyl)diphenylphosphine oxide, and a silver (Ag) electrode layer formed on the electron transport layer.

Moreover, the present invention provides a perovskite light-emitting device comprising an emission layer including a metal halide perovskite.

The present invention also provides a device wherein the metal halide perovskite is represented by any one of Formulas 2 to 7.

ABX₃ [Formula 2]

A₂BX₄ [Formula 3]

A₃BX₅ [Formula 4]

A₄BX₆ [Formula 5]

ABX₄ [Formula 6]

Aₙ₋₁PbₙX₃ₙ₊₁ (where n is an integer from 2 to 6) [Formula 7]

(In Formulas 2 to 7,
A includes an organic ammonium ion, an organic amidinium ion, an organic phosphonium ion, an alkali metal ion, or derivatives thereof;
B includes a transition metal, a rare-earth metal, an alkaline earth metal, an organic compound, an inorganic compound, ammonium, derivatives thereof, or a combination thereof;
X includes a halogen ion or a combination of different halogen ions.)

Furthermore, in another aspect, the present invention provides a method for manufacturing a device, comprising:
(A) forming a first electrode on a substrate;
(B) forming a hole transport layer on the first electrode;
(C) forming a photoactive layer on the hole transport layer;
(D) forming an electron transport layer including the organic monomolecular compound on the photoactive layer; and
(E) forming a second electrode on the electron transport layer.

Additionally, the present invention provides a method for manufacturing a device, wherein, in step (D), the electron transport layer including the organic monomolecular compound is formed on the active layer using any one method selected from the group consisting of spin coating, dip coating, bar coating, spray coating, slot-die coating, gravure coating, blade coating, screen printing, nozzle printing, inkjet printing, and electrospinning.

### Advantageous Effects

The organic monomolecular compound according to the present invention has an alkoxy functional group in a structure comprising a quinoxaline--based compound and a triphenylphosphine oxide-based compound, thereby exhibiting excellent thermal stability, low absorption in the visible light region, and a wide bandgap energy, resulting in superior electron transport capability. Accordingly, it can be utilized as an electron transport material in various devices, such as organic or perovskite light-emitting devices. Additionally, in contrast to other functional groups, it allows modification of electron transport properties through various property adjustments.

In particular, the organic monomolecular compound according to the present invention, due to the presence of an alkoxy functional group in the quinoxaline-based and triphenylphosphine oxide-based compounds, enables efficient control of the molecular dipole moment. Furthermore, as it is readily soluble in alcohol-based solvents, it allows the formation of an electron transport layer suitable for large-area optoelectronic devices through a simple solution process.

Moreover, in one embodiment of the present invention, the light-emitting device includes the aforementioned organic monomolecular compound in the electron transport layer, thereby achieving high luminous efficiency and high external quantum efficiency (EQE).

### DESCRIPTION OF DRAWINGS

FIG. 1 is a diagram illustrating the synthesis route of the organic monomolecular compound (MQxTPPO1) according to the embodiment.

FIG. 2 is a diagram illustrating the synthesis route of the organic monomolecular compounds (QxTPPO1 and FQxTPPO1) according to the comparative example.

FIG. 3 shows the absorbance measurement results of films containing the organic monomolecular compounds according to the embodiment and the comparative example.

FIG. 4 shows the cyclic voltammetry (CV) analysis results of the organic monomolecular compounds according to the embodiment and the comparative example.

FIG. 5 shows the thermogravimetric analysis (TGA) results of the organic monomolecular compounds according to the embodiment and the comparative example.

FIG. 6 shows the measurement results of the luminance, luminous efficiency, current-voltage characteristics, and external quantum efficiency (EQE) of organic light-emitting devices in which the organic monomolecular compounds are included in the electron transport layer, according to the embodiment and the comparative example.

### DETAILED DESCRIPTION

In the following description of the present invention, a detailed description of known functions and configurations incorporated herein will be omitted when it may make the subject matter of the present disclosure unclear.

The embodiments according to the concept of the present invention can be variously modified and can take various forms, so that the embodiments are illustrated in the drawings and described in detail herein. It should be understood, however, that the embodiments according to the concepts of the present invention are not limited to the specific forms disclosed, but include modifications, equivalents, or alternatives falling within the spirit and scope of the present invention.

The terms used herein are used for explaining a specific exemplary embodiment, not limiting the present inventive concept. Thus, the expression of singularity herein includes the expression of plurality unless clearly specified otherwise in context. The terms such as “include” or “comprise” used herein may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

In addition, unless otherwise specified, the following terms and phrases used herein have the following meanings.

The term “substituted or unsubstituted” refers to any substituent that, unless otherwise stated, includes an alkyl group having 1 to 50 carbon atoms (preferably 1 to 18, more preferably 1 to 8), a cycloalkyl group having 3 to 50 ring-forming carbon atoms (preferably 3 to 10, more preferably 3 to 8, even more preferably 5 or 6), and an aryl group having 6 to 50 ring-forming carbon atoms (preferably 6 to 25, more preferably 6 to 18). It also includes an aralkyl group having 7 to 51 carbon atoms (preferably 7 to 30, more preferably 7 to 20), in which the aryl moiety contains 6 to 50 ring-forming carbon atoms (preferably 6 to 25, more preferably 6 to 18), as well as an amino group. A mono-substituted or di-substituted amino group may have a substituent selected from an alkyl group with 1 to 50 carbon atoms (preferably 1 to 18, more preferably 1 to 8) and an aryl group with 6 to 50 ring-forming carbon atoms (preferably 6 to 25, more preferably 6 to 18). An alkoxy group may contain an alkyl group with 1 to 50 carbon atoms (preferably 1 to 18, more preferably 1 to 8), while an aryloxy group may have an aryl group with 6 to 50 ring-forming carbon atoms (preferably 6 to 25, more preferably 6 to 18). A mono-, di-, or tri-substituted silyl group may have a substituent selected from an alkyl group with 1 to 50 carbon atoms (preferably 1 to 18, more preferably 1 to 8) and an aryl group with 6 to 50 ring-forming carbon atoms (preferably 6 to 25, more preferably 6 to 18). A heteroaryl group may have 5 to 50 ring-forming atoms (preferably 5 to 24, more preferably 5 to 13) and contain 1 to 5 heteroatoms (preferably 1 to 3, more preferably 1 to 2) selected from nitrogen, oxygen, and sulfur. A haloalkyl group may have 1 to 50 carbon atoms (preferably 1 to 18, more preferably 1 to 8), where one or more (preferably 1 to 15, more preferably 1 to 7) hydrogen atoms are substituted with the same or different halogen atoms (fluorine, chlorine, bromine, iodine). Additionally, it includes halogen atoms (fluorine, chlorine, bromine, iodine), a cyano group, and a nitro group.

A sulfonyl group may have a substituent selected from an alkyl group with 1 to 50 carbon atoms (preferably 1 to 18, more preferably 1 to 8) and an aryl group with 6 to 50 ring-forming carbon atoms (preferably 6 to 25, more preferably 6 to 18). A di-substituted phosphoryl group may also have a substituent selected from an alkyl group with 1 to 50 carbon atoms (preferably 1 to 18, more preferably 1 to 8) and an aryl group with 6 to 50 ring-forming carbon atoms (preferably 6 to 25, more preferably 6 to 18). Other substituents include alkylsulfonyl oxy, arylsulfonyl oxy, alkylcarbonyl oxy, arylcarbonyl oxy, boron-containing groups, zinc-containing groups, tin-containing groups, silicon-containing groups, magnesium-containing groups, lithium-containing groups, hydroxyl groups, alkyl- or aryl-substituted carbonyl groups, carboxyl groups, vinyl groups, (meth)acryloyl groups, epoxy groups, and oxetanyl groups. At least one of these substituents is preferred. Additionally, a substituent may be further substituted by any of the aforementioned substituents. Furthermore, substituents may bond with each other to form a ring.

The term “ring-forming carbon number” refers to the number of carbon atoms that constitute the ring in a cyclic structure, such as a monocyclic compound, a fused-ring compound, a bridged compound, a carbocyclic compound, or a heterocyclic compound. When the ring is substituted, the carbon atoms included in the substituent are not counted in the ring-forming carbon number. For example, a benzene ring has a ring-forming carbon number of 6, a naphthalene ring has a ring-forming carbon number of 10, a pyridinyl group has a ring-forming carbon number of 5, and a furanyl group has a ring-forming carbon number of 4. When an alkyl group is substituted on a benzene or naphthalene ring, the carbon number of the alkyl group is not included in the ring-forming carbon number. Likewise, when a fluorene ring is bonded as a substituent (including spirofluorene structures), the carbon number of the fluorene ring as a substituent is not counted in the ring-forming carbon number.

The term “ring-forming atom number” refers to the number of atoms that constitute the ring in a cyclic structure, such as a monocyclic compound, a fused-ring compound, or a ring assembly. Atoms that do not constitute the ring (e.g., terminal hydrogen atoms bonded to the ring-forming atoms) or atoms in substituents bonded to the ring are not included in the ring-forming atom number. For example, a pyridine ring has a ring-forming atom number of 6, a quinazoline ring has a ring-forming atom number of 10, and a furan ring has a ring-forming atom number of 5. The hydrogen atoms or substituent atoms bonded to the ring-forming carbon atoms of pyridine or quinazoline are not included in the ring-forming atom number. Similarly, when a fluorene ring is bonded as a substituent (including spirofluorene structures), the atom number of the fluorene ring as a substituent is not counted in the ring-forming atom number.

Hereinafter, the present disclosure will be described in detail.

The organic monomolecular compound according to the present invention is characterized by having an alkoxy functional group in a chemical structure comprising a quinoxaline-based compound and a triphenylphosphine oxide-based compound, as represented by Formula 1.

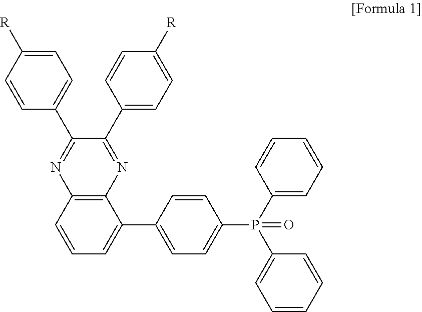

(In Formula 1, R is a substituted or unsubstituted alkoxy group.)

The organic monomolecular compound according to the present invention can be included in electron transport functional layers, such as electron transport layers and electron injection layers, in various devices, including organic or perovskite optoelectronic devices such as organic solar cells (OSC), organic light-emitting devices (OLED), perovskite solar cells (PSC), and perovskite light-emitting devices (PeLED).

For example, the organic monomolecular compound of the present invention can be included in either the first charge transport layer or the second charge transport layer, which serves as an electron transport layer, in a device comprising a substrate, a first electrode disposed on the substrate, a first charge transport layer disposed on the first electrode, a photoactive layer disposed on the first charge transport layer, a second charge transport layer disposed on the photoactive layer, and a second electrode disposed on the electron transport layer.

Preferably, the device may comprise a substrate, a first electrode disposed on the substrate, a hole transport layer disposed on the first electrode, an active layer disposed on the hole transport layer, an electron transport layer disposed on the active layer and including the organic monomolecular compound according to the present invention, and a second electrode disposed on the electron transport layer.

In this case, the substrate serves as the support for the device and is composed of a transparent material. It may be made of a flexible or rigid material, and examples of such materials include light-transmissive glass or polymer materials such as polycarbonate (PC), polyethylene terephthalate (PET), polyethylene naphthalate (PEN), polyimide (PI), and polypropylene (PP).

In the structure of the device, the first electrode functions as an anode through which holes are injected and may be made of a conductive metal oxide, metal, metal alloy, or carbon-based material. The conductive metal oxide may include indium tin oxide (ITO), fluorine tin oxide (FTO), aluminum zinc oxide (AZO), gallium zinc oxide (GZO), indium zinc oxide (IZO), zinc tin oxide (ZTO), indium zinc tin oxide (IZTO), indium gallium zinc oxide (IGZO), or a combination thereof.

The hole transport layer disposed on the first electrode may include at least one selected from the group consisting of poly(ethylenedioxythiophene):polystyrene sulfonate (PEDOT:PSS), poly[(9,9-dioctyl-fluorenyl-2,7-diyl)-co-(4,4′-(N-(p-butylphenyl))diphenylamine)](TFB), poly(9-vinylcarbazole) (PVK), N,N,N′,N′-tetrakis(4-methoxyphenyl)-benzidine (TPD), poly-TPD, 4,4′,4″-tris(N-carbazolyl)-triphenylamine (TCTA), N,N′-bis(naphthalen-1-yl)-N,N′-bis(phenyl)-9,9-spiro-bifluorene (spiro-NPB), dipyrazino[2,3-f:2′,3′-h]quinoxaline-2,3,6,7,10,11-hexacarbonitrile (HATCN), 1,1-bis[(di-4-tolylamino)phenylcyclohexane (TAPC), VNPB (N4,N4′-Di(naphthalen-1-yl)-N4,N4′-bis(4-vinylphenyl)biphenyl-4,4′-diamine), and p-type metal oxides.

The active layer disposed on the hole transport layer may function as an emission layer or a light-absorbing layer, depending on the type of device. In the following description, the active layer is exemplified as a perovskite active layer including a perovskite material.

The perovskite active layer is preferably composed of a metal halide perovskite represented by any one of Formulas 2 to 7 below.

ABX₃ [Formula 2]

A₂BX₄ [Formula 3]

A₃BX₅ [Formula 4]

A₄BX₆ [Formula 5]

ABX₄ [Formula 6]

Aₙ₋₁PbₙX₃ₙ₊₁ (where n is an integer from 2 to 6) [Formula 7]

In Formulas 2 to 7, A may be an organic ammonium ion, an organic amidinium ion, an organic phosphonium ion, an alkali metal ion, or a derivative thereof. Examples of organic ammonium ions include (CH₃NH₃)ₙ, ((CₓH₂ₓ₊₁)ₙNH₃)₂(CH₃NH₃)ₙ, (CₙH₂ₙ₊₁NH₃)₂, (CF₃NH₃)ₙ, ((CₓF₂ₓ₊₁)ₙNH₃)₂(CF₃NH₃)ₙ, ((CₓF₂ₓ₊₁)ₙNH₃)₂ [symbol] (CₙF₂ₙ₊₁NH₃)₂ (where n and x are integers equal to [symbol] or greater than 1). The organic amidinium may include formamidinium (NH₂CH═NH⁺), acetamidinium (NH₂C(CH)═NH²⁺), or guanidinium (NHC(NH)═NH⁺).

Furthermore, B may include a transition metal, a rare-earth metal, an alkaline earth metal, Pb, Sn, Ge, Ga, In, Al, Sb, Bi, Po, an organic compound, an inorganic compound, ammonium, derivatives thereof, or combinations thereof.

Additionally, X may include a halogen element such as Cl, Br, or I, or a combination thereof.

Meanwhile, the perovskite active layer may be a bulk polycrystalline thin film or a thin film composed of nanocrystalline particles. The perovskite bulk polycrystalline thin film is formed through a process in which crystallization and thin film coating occur simultaneously as the solvent evaporates while spin-coating a solution containing a transparent ionic form of a perovskite precursor.

In contrast, a perovskite nanocrystalline particle thin film is obtained by first crystallizing nanoscale particles in a colloidal solution and then stably dispersing them in the solution using ligands. The perovskite nanocrystalline particles may further include multiple organic ligands surrounding their surface, and the organic ligands may be composed of alkyl halides or carboxylic acids.

The electron transport layer disposed on the active layer comprises the organic monomolecular compound represented by Formula 1 in the present invention. Notably, the organic monomolecular compound according to the present invention exhibits excellent solubility in alcohol-based solvents, enabling the easy formation of an electron transport layer on the active layer via a solution process.

The second electrode formed on the electron transport layer functions as a cathode for electron injection and may be composed of a metal such as Ag, Al, Mg, Ca, Na, K, In, Y, Li, Pb, or Cs, or a combination thereof.

Additionally, the device described above may further include a hole injection layer between the first electrode and the hole transport layer to facilitate hole injection. Similarly, an electron injection layer may be disposed between the second electrode and the electron transport layer to facilitate electron injection.

The hole injection layer may include conventionally known hole transport materials and may be composed of two or more layers containing different hole transport materials. The electron injection layer may include LiF, NaCl, CsF, Li₂O, BaO, BaF₂.

Furthermore, the electron transport layer may also function as a hole-blocking layer, and the hole transport layer may function as an electron-blocking layer. If necessary, a hole-blocking layer may be additionally disposed between the perovskite active layer and the electron transport layer, and an electron-blocking layer may be additionally disposed between the perovskite active layer and the hole transport layer.

The hole-blocking layer serves to prevent triplet excitons or holes from diffusing toward the second electrode (cathode) and may be selected arbitrarily from known hole-blocking materials. Examples include oxadiazole derivatives, triazole derivatives, phenanthroline derivatives, and TSPO1 (diphenylphosphine oxide-4-(triphenylsilyl)phenyl).

Next, as a method for manufacturing the device described in detail above, each step of the process is explained, which includes (A) forming a first electrode on a substrate, (B) forming a hole transport layer on the first electrode, (C) forming a photoactive layer on the hole transport layer, (D) forming an electron transport layer containing the organic monomolecular compound of the present invention on the photoactive layer, and (E) forming a second electrode on the electron transport layer.

In step (A), a substrate made of glass or plastic is prepared, and a first electrode comprising a conductive metal oxide such as ITO, FTO, AZO, GZO, IZO, ZTO, IZTO, or IGZO is formed on the substrate through physical vapor deposition (PVD) methods such as sputtering, thermal evaporation, or electron beam evaporation, or through chemical vapor deposition (CVD).

In step (B), a solution containing a material with hole transport properties is prepared, and a hole transport layer is formed on the first electrode using one of the following methods: spin coating, dip coating, bar coating, spray coating, slot-die coating, gravure coating, blade coating, screen printing, nozzle printing, inkjet printing, or electrospinning.

The material with hole transport properties may include at least one selected from the group consisting of poly(ethylenedioxythiophene):polystyrene sulfonate (PEDOT:PSS), poly[(9,9-dioctyl-fluorenyl-2,7-diyl)-co-(4,4′-(N-(p-butylphenyl))diphenylamine)](TFB), poly(9-vinylcarbazole) (PVK), N,N,N′,N′-tetrakis(4-methoxyphenyl)-benzidine (TPD), poly-TPD, 4,4′,4″-tris(N-carbazolyl)-triphenylamine (TCTA), N,N′-bis(naphthalen-1-yl)-N,N′-bis(phenyl)-9,9-spiro-bifluorene (spiro-NPB), dipyrazino[2,3-f:2′,3′-h]quinoxaline-2,3,6,7,10,11-hexacarbonitrile (HATCN), 1,1-bis[(di-4-tolylamino)phenylcyclohexane (TAPC), VNPB (N4,N4′-Di(naphthalen-1-yl)-N4,N4′-bis(4-vinylphenyl)biphenyl-4,4′-diamine), and p-type metal oxides.

In step (C), a perovskite active layer is formed on the hole transport layer using one of the following methods: spin coating, dip coating, bar coating, spray coating, slot-die coating, gravure coating, blade coating, screen printing, nozzle printing, inkjet printing, or electrospinning. The perovskite material may have a structure represented by ABX₃, A₂BX₄, A₃BX₅, A₄BX₆, ABX₄, Aₙ₋₁PbₙX₃ₙ₊₁ (where n is an integer from 2 to 6), as described previously.

Next, step (D) involves forming an electron transport layer containing the organic monomolecular compound of the present invention on the perovskite active layer. In this step, a solution containing the organic monomolecular compound is prepared, and the electron transport layer is formed on the perovskite active layer using one of the following methods: spin coating, dip coating, bar coating, spray coating, slot-die coating, gravure coating, blade coating, screen printing, nozzle printing, inkjet printing, or electrospinning.

Finally, in step (E), a second electrode is formed on the electron transport layer by physical vapor deposition (PVD) methods such as sputtering, thermal evaporation, or electron beam evaporation, or by chemical vapor deposition (CVD). The second electrode may comprise a metal such as Ag, Al, Mg, Ca, Na, K, In, Y, Li, Pb, or Cs, or a combination thereof.

As described in detail above, the organic monomolecular compound of the present invention has an alkoxy functional group in a structure comprising a quinoxaline-based compound and a triphenylphosphine oxide-based compound. This structure provides excellent thermal stability, low absorption in the visible light region, and a wide bandgap energy, resulting in superior electron transport capability. Therefore, the compound can be utilized as an electron transport material in various devices, including organic or perovskite light-emitting devices. Additionally, unlike other functional groups, it allows modification of electron transport properties through various property adjustments.

In particular, the organic monomolecular compound of the present invention enables efficient control of molecular dipole moments due to the presence of an alkoxy functional group in the quinoxaline-based and triphenylphosphine oxide-based compounds. Furthermore, since it is readily soluble in alcohol-based solvents, it facilitates the formation of an electron transport layer suitable for large-area optoelectronic devices using a simple solution process.

Moreover, in one embodiment of the present invention, the light-emitting device includes the aforementioned organic monomolecular compound in the electron transport layer, thereby achieving high luminous efficiency and high external quantum efficiency (EQE).

### MODE FOR INVENTION

Hereinafter, the present disclosure will be described in more detail with reference to an embodiment.

The embodiment according to the present specification may be modified in many different forms, and the scope of the present specification is not construed as being limited to the embodiment described below. The embodiment of the present disclosure described hereinbelow is provided for allowing those skilled in the art to more clearly comprehend the present disclosure.

### [Example] Synthesis of the Organic Monomolecular Compound (MQxTPPO1)

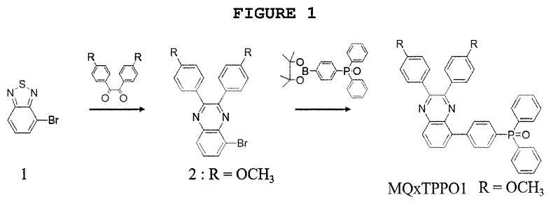

The organic monomolecular compound MQxTPPO1 according to the present invention was synthesized following the synthesis route illustrated in FIG. 1.

### 1. Synthesis of 5-Bromo-2,3-bis(4-methoxyphenyl)quinoxaline (Compound 2)

Compound 1 (8 mmol) was dissolved in 30 mL of acetic acid, and sodium borohydride (NaBH₄, 160 mmol) was slowly added in portions. The reaction temperature was controlled at 0° C., then gradually increased to room temperature, and the mixture was stirred for 12 hours. After the reaction was completed, the mixture was extracted with diethyl ether, and the solvent was removed. Subsequently, 1,2-bis(4-methoxyphenyl)ethene-1,2-dione (8.8 mmol) was added to the residue in 20 mL of ethanol and 10 mL of acetic acid. The reaction mixture was stirred at 110° C. for 12 hours, extracted with dichloromethane, and purified by column chromatography, yielding a white solid compound (Compound 2).

¹H-NMR (400 MHz, CDCl₃) δ 8.02(ddd, J=21.3, 8.0, 1.4 Hz, 2n), 7.60 (dd, J=6.6, 2.1 Hz, 2n), 7.50-7.56 (m, 3n), 6.87 (td, J=7.0, 2.0 Hz, 4n), 3.82 (s, 6n). ¹³C-NMR (100 MHz, CDCl₃) δ 160.64, 160.51, 153.58, 153.28, 141.72, 138.75, 132.92, 131.82, 131.31, 131.12, 129.71, 128.83, 124.03, 113.99, 113.83, 55.43.

### 2. Synthesis of (4-(2,3-bis(4-methoxyphenyl)quinoxalin-5-yl)phenyl)diphenylphosphine oxide (MQxTPPO1)

Compound 2 (1 mmol), diphenyl(4-(4,4,5,5-tetramethyl-1,3,2-dioxaborolan-2-yl)phenyl)phosphine oxide (1.2 mmol), tetrakis(triphenylphosphine)palladium(0)(Pd(PPh₃)₄, 5 mol %), and potassium carbonate (2M, 5 mL) were dissolved in 12 mL of toluene. The mixture was stirred at 90° C. under a nitrogen atmosphere for 24 hours. After completion of the reaction, the mixture was extracted with dichloromethane, purified by column chromatography, and further purified by recrystallization, yielding a white solid compound (MQxTPPO1).

¹H-NMR (400 MHz, CDCl₃) δ 8.12 (q, J=3.4 Hz, in), 7.91 (dd, J=8.2, 2.7 Hz, 2n), 7.72-7.82 (m, 8n), 7.53-7.57 (m, 4n), 7.45-7.50 (m, 6n), 6.88 (d, J=4.6 Hz, 2n), 6.79 (d, J=6.9 Hz, 2n), 3.81 (d, J=10.1 Hz, 6n). ¹³C-NMR (100 MHz, CDCl₃) δ 160.38, 160.33, 152.67, 152.11, 142.23, 141.01, 138.94, 138.48, 133.28, 132.34, 132.25, 132.06, 132.04, 131.83, 131.74, 131.61, 131.40, 131.23, 131.11, 130.98, 130.62, 130.16, 129.28, 128.68, 128.57, 113.99, 113.75, 55.44, 55.39. ³¹P-NMR (162 MHz, CDCl₃) δ 29.79. GC-MS: m/z calcd, 618.21; found, 618.20 [M+].

### [Comparative Example] Synthesis of Organic Monomolecular Compounds (QxTPPO1 and FQxTPPO1)

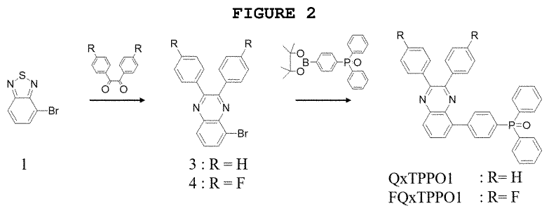

The organic monomolecular compounds QxTPPO1 (Comparative Example 1) and FQxTPPO1 (Comparative Example 2) were synthesized following the synthesis route illustrated in FIG. 2.

### 1. Synthesis of 5-Bromo-2,3-bis(4-fluorophenyl)quinoxaline (Compound 4)

Compound 1 (8 mmol) was dissolved in 30 mL of acetic acid, and sodium borohydride (NaBH₄, 160 mmol) was slowly added in portions. The reaction temperature was controlled at 0° C., then gradually increased to room temperature, and the mixture was stirred for 12 hours. After the reaction was completed, the mixture was extracted with diethyl ether, and the solvent was removed. Subsequently, 1,2-bis(4-fluorophenyl)ethene-1,2-dione (8.8 mmol) was added to the residue in 20 mL of ethanol and 10 mL of acetic acid. The reaction mixture was stirred at 110° C. for 12 hours, extracted with dichloromethane, and purified by column chromatography, yielding a white solid compound (Compound 4).

¹H-NMR (400 MHz, CDCl₃) δ 8.07 (ddd, J=11.0, 7.8, 1.4 Hz, 2n), 7.50-7.62 (m, 5n), 7.02-7.08 (m, 4n). ¹³C-NMR (100 MHz, CDCl₃) δ 164.86, 164.74, 162.36, 162.26, 152.77, 152.48, 141.89, 138.93, 134.60, 134.40, 133.58, 132.34, 132.26, 131.91, 131.82, 130.42, 128.96, 124.20, 115.89, 115.74, 115.68, 115.53.

### 2. Synthesis of (4-(2,3-bis(4-fluorophenyl)quinoxalin-5-yl)phenyl)diphenylphosphine oxide (FQxTPPO1)

Compound 4 (1 mmol), diphenyl(4-(4,4,5,5-tetramethyl-1,3,2-dioxaborolan-2-yl)phenyl)phosphine oxide (1.2 mmol), tetrakis(triphenylphosphine)palladium(0)(Pd(PPh₃I), 5 mol %), and potassium carbonate (2M, 5 mL) were dissolved in 12 mL of toluene. The mixture was stirred at 90° C. under a nitrogen atmosphere for 24 hours. After completion of the reaction, the mixture was extracted with dichloromethane, purified by column chromatography, and further purified by recrystallization, yielding a white solid compound (FQxTPPO1).

¹H-NMR (400 MHz, CDCl₃) δ 8.15 (dd, J=5.9, 4.1 Hz, In), 7.72-7.89 (m, 10n), 7.44-7.57 (m, 10n), 6.94-7.08 (m, 4n). ¹³C-NMR (100 MHz, CDCl₃) δ 164.66, 162.18, 162.12, 151.90, 151.36, 141.88, 141.20, 139.28, 138.68, 135.08, 134.70, 133.24, 132.31, 132.22, 132.09, 132.02, 131.90, 131.82, 131.74, 131.02, 130.89, 130.76, 129.97, 129.41, 128.68, 128.57, 115.85, 115.63, 115.41. ¹⁹F-NMR (376 MHz, CDCl₃) δ −111.50. ³¹P-NMR (162 MHz, CDCl₃) δ 29.68. GC-MS: m/z calcd, 594.17; found, 594.15 [M+].

### Experimental Example

### 1. Evaluation of the Properties of Organic Monomolecular Compounds in the Embodiments and Comparative Examples

### 1) Optical Evaluation

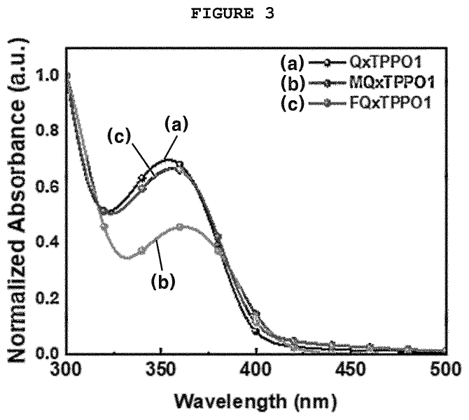

To evaluate the optical properties of the embodiments and comparative examples, the optical characteristics of the films were measured in the wavelength range of 300-550 nm, and the results are shown in FIG. 3.

### 2) Electrochemical Property Evaluation

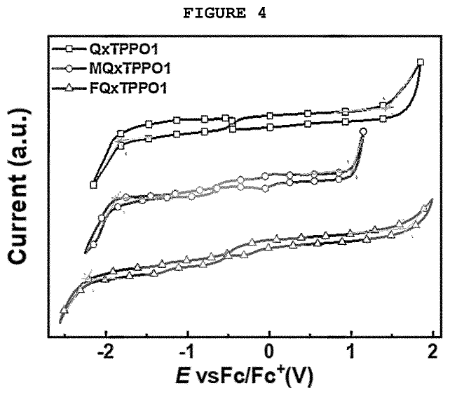

To evaluate the electrochemical properties of the embodiments and comparative examples, cyclic voltammetry (CV) was performed to measure oxidation potentials and reduction potentials. The HOMO and LUMO energy levels of the embodiments and comparative examples were also measured, and the results are presented in FIG. 4.

The CV analysis was conducted at room temperature under nitrogen gas using a 0.1M solution of tetrabutylammonium tetrafluorophosphate (Bu₄N(PF₆)) in acetonitrile as the electrolyte solution.

### 3) Thermal Property Evaluation

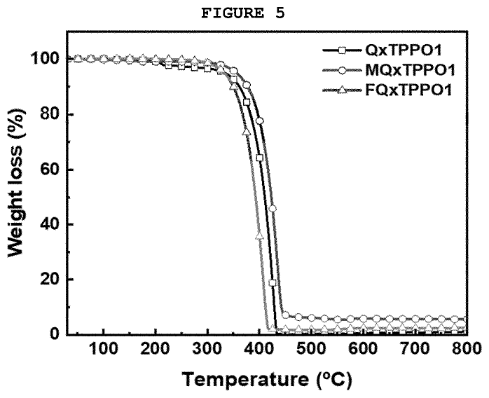

To assess the thermal stability of the embodiments and comparative examples, thermal gravimetric analysis (TGA) was conducted to measure the decomposition temperature (Td), and the results are shown in FIG. 5.

### 2. Evaluation of the Organic Light-Emitting Device Containing the Organic Monomolecular Compounds in the Embodiments and Comparative Examples

### 1) Fabrication of the Organic Light-Emitting Device

A semi-transparent electrode of indium tin oxide (ITO) was formed on a glass substrate. A conductive polymer (PEDOT:PSS, Al 4083, Clevios) was then coated onto the ITO electrode to form a hole transport layer.

Next, a polymeric super yellow fluorescent material, poly(phenylvinylene), was deposited as the active layer on the hole transport layer. An electron transport layer was then formed by solution processing, where the organic monomolecular compounds from the embodiments and comparative examples were dissolved in isopropyl alcohol (IPA) and coated onto the active layer.

Finally, an aluminum (Al) metal electrode was deposited on the electron transport layer to complete the fabrication of the light-emitting device.

### 2) Evaluation of the Organic Light-Emitting Device Characteristics

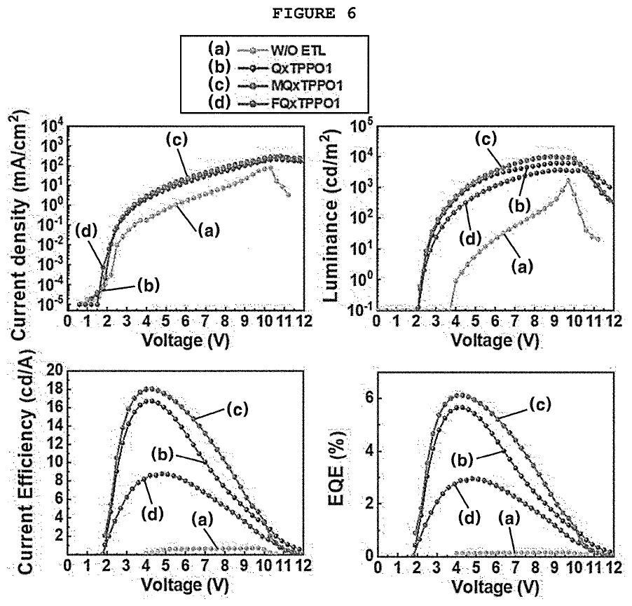

The current-voltage (I-V) curve, luminance (cd/m²), luminous efficiency (cd/A), external quantum efficiency (EQE), and turn-on voltage (V) were measured for light-emitting devices, including those without an electron transport layer, as well as those containing the embodiments and comparative examples. The results are presented in FIG. 6 and summarized in Table 1 below.

TABLE 1

| | L ₘₐₓ | LE ₘₐₓ | | Turn-on |
|---|---|---|---|---|
| | [cd/m2] | [cd/A] | EQE ₘₐₓ | Voltage [V] |
| Device configuration(OLEDs) | @ bias | @ bias | [%] @ bias | @ 1 cd/m² |
| ITO/PEDOT:PSS/SY/A1 | 1633@9.7 | 0.72@9.4 | 0.16@9.4 | 4.0 |
| ITO/PEDOT:PSS/SY/QxTPPO1/A1 | 6211@9.1 | 16.69@4.3 | 5.65@4.3 | 2.5 |
| ITO/PEDOT:PSS/SY/MQxTPPO1/A1 | 10030@8.8 | 17.98@4.3 | 6.12@4.3 | 2.5 |
| ITO/PEDOT:PSS/SY/FQxTPPO1/A1 | 3723@10.5 | 8.76@4.8 | 2.94@4.8 | 2.5 |

Based on Table 1, the light-emitting device of the embodiment exhibited a turn-on voltage of 2.5V, which is lower than the turn-on voltage of 4.0V observed in the device without an electron transport layer. This indicates that electron injection into the electron transport layer occurs smoothly in the embodiment.

Additionally, the external quantum efficiency (EQE) of the light-emitting device incorporating the embodiment was measured at 6.12%. In contrast, the EQE of the light-emitting devices containing the comparative examples was measured at 5.65% and 2.94%, respectively. These results confirm that the embodiment enables the formation of a more efficient electron transport layer due to its functional group-based chemical structure, compared to the comparative examples.

The present invention is not limited to the above embodiments, but can be manufactured in a variety of different forms. Those skilled in the art to which the present invention pertains will understand that other specific forms can be implemented without changing the technical spirit or essential features of the present invention. Therefore, it should be understood that the aforementioned embodiments are given by way of illustration only, and are not intended to be limiting in all aspects.

### INDUSTRIAL APPLICABILITY

The organic monomolecular compound according to the present invention can be utilized as an electron transport material in various devices, including organic and perovskite light-emitting devices.

1. An organic monomolecular compound represented by the following Formula 1: 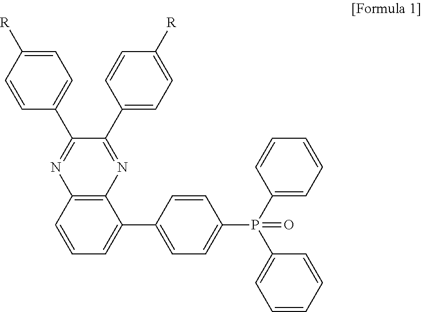
(In Formula 1, R is a substituted or unsubstituted alkoxy group having 1 to 20 carbon atoms.)

2. The organic monomolecular compound according to claim 1, wherein R in Formula 1 is a methoxy group.

3. A device comprising a layer including the organic monomolecular compound according to claim 1.

4. The device according to claim 3, comprising:
a substrate;
a first electrode disposed on the substrate;
a first charge transport layer disposed on the first electrode;
an active layer disposed on the first charge transport layer;
a second charge transport layer disposed on the active layer; and
a second electrode disposed on an electron transport layer,
wherein the first charge transport layer or the second charge transport layer comprises the organic monomolecular compound.

5. The device according to claim 4, wherein the substrate is made of glass or plastic.

6. The device according to claim 4, wherein the first electrode comprises at least one selected from the group consisting of indium tin oxide (ITO), fluorine tin oxide (FTO), aluminum zinc oxide (AZO), gallium zinc oxide (GZO), indium zinc oxide (IZO), zinc tin oxide (ZTO), indium zinc tin oxide (IZTO), and indium gallium zinc oxide (IGZO).

7. The device according to claim 4, comprising:
a substrate;
a first electrode disposed on the substrate;
a hole transport layer disposed on the first electrode;
an active layer disposed on the hole transport layer;
an electron transport layer disposed on the active layer and including the organic monomolecular compound; and
a second electrode disposed on the electron transport layer.

8. The device according to claim 7, wherein the hole transport layer comprises at least one selected from the group consisting of poly(ethylenedioxythiophene):polystyrene sulfonate (PEDOT:PSS), poly[(9,9-dioctyl-fluorenyl-2,7-diyl)-co-(4,4′-(N-(p-butylphenyl))diphenylamine)](TFB), poly(9-vinylcarbazole) (PVK), N,N,N′,N′-tetrakis(4-methoxyphenyl)-benzidine (TPD), poly-TPD, 4,4′,4″-tris(N-carbazolyl)-triphenylamine (TCTA), N,N′-bis(naphthalen-1-yl)-N,N′-bis(phenyl)-9,9-spiro-bifluorene (spiro-NPB), dipyrazino[2,3-f:2′,3′-h]quinoxaline-2,3,6,7,10,11-hexacarbonitrile (HATCN), 1,1-bis[(di-4-tolylamino)phenylcyclohexane (TAPC), VNPB (N4,N4′-Di(naphthalen-1-yl)-N4,N4′-bis(4-vinylphenyl)biphenyl-4,4′-diamine), and p-type metal oxides.

9. The device according to claim 7, further comprising a hole injection layer disposed between the first electrode and the hole transport layer, and an electron injection layer disposed between the second electrode and the electron transport layer.

10. The device according to claim 7, comprising:
a glass substrate;
an ITO electrode formed on the glass substrate;
a hole transport layer formed on the ITO electrode and including PEDOT:PSS;
a light-emitting layer formed on the hole transport layer and including poly(phenylvinylene);
an electron transport layer formed on the light-emitting layer and including (4-(2,3-bis(4-methoxyphenyl)quinoxalin-5-yl)phenyl)diphenylphosphine oxide [(4-(2,3-bis(4-methoxyphenyl)quinoxali-5-yl)phenyl)diphenylphosphine oxide]; and
a silver (Ag) electrode layer formed on the electron transport layer,
wherein the device has a sequentially laminated structure.

11. The device according to claim 7, wherein the device is a perovskite light-emitting device comprising a light-emitting layer including a metal halide perovskite.

12. The device according to claim 11, wherein the metal halide perovskite is represented by any one of Formulas 2 to 7 below:
ABX₃ [Formula 2]
A₂BX₄ [Formula 3]
A₃BX₅ [Formula 4]
A₄BX₆ [Formula 5]
ABX₄ [Formula 6]
Aₙ₋₁PbₙX₃ₙ₊₁ (where n is an integer from 2 to 6) [Formula 7]
(In Formulas 2 to 7,
A includes an organic ammonium ion, an organic amidinium ion, an organic phosphonium ion, an alkali metal ion, or a derivative thereof;
B includes a transition metal, a rare-earth metal, an alkaline earth metal, an organic compound, an inorganic compound, ammonium, derivatives thereof, or a combination thereof;
X includes a halogen ion or a combination of different halogen ions.)

13. A method for manufacturing a device, comprising:
(A) forming a first electrode on a substrate;
(B) forming a hole transport layer on the first electrode;
(C) forming an active layer on the hole transport layer;
(D) forming an electron transport layer including the organic monomolecular compound according to claim 1 on the active layer; and
(E) forming a second electrode on the electron transport layer.

14. The method for manufacturing a device according to claim 13, wherein step (D) is performed using one of the following methods:
spin coating, dip coating, bar coating, spray coating, slot-die coating, gravure coating, blade coating, screen printing, nozzle printing, inkjet printing, or electrospinning.
